(19) United States
(12) Patent Application Publication
(10) Pub. No.: US 2026/0323916 A1
(43) Pub. Date: Oct. 15, 2026

(54) SEMICONDUCTOR MEMORY DEVICE INCLUDING VERTICAL CHANNEL TRANSISTORS AND METHOD FOR FABRICATING THE SAME

(71) Applicant: Samsung Electronics Co., Ltd., Suwon-si (KR)

(72) Inventors: Chang Sik KIM, Suwon-si (KR); Chang Sik YOO, Suwon-si (KR); Jae Joon SONG, Suwon-si (KR)

(21) Appl. No.: 19/630,619

(22) Filed: Mar. 27, 2026

(30) Foreign Application Priority Data
Apr. 10, 2025 (KR) 10-2025-0046586

(51) Int. Cl. H10B 12/00

(52) U.S. Cl. CPC H10B 12/315; H10B 12/05

(57) ABSTRACT

A semiconductor memory device includes an active pattern which includes a first portion and a second portion connected along a vertical direction, a conductive line which is connected to the active pattern on a lower surface of the active pattern, and extends in a first horizontal direction intersecting the vertical direction, a first gate pattern which extends in a second horizontal direction intersecting the vertical direction and the first horizontal direction on a side face of the first portion of the active pattern, a second gate pattern which is spaced apart from the first gate pattern on a side face of the second portion of the active pattern, and extends in the second horizontal direction, and a data storage structure which is connected to the active pattern on an upper surface of the active pattern.

### CROSS-REFERENCE TO RELATED APPLICATION

This application claims the benefit of an earlier filing date and right of priority under 35 USC § 119 to Korean Patent Application No. 10-2025-0046586 filed on Apr. 10, 2025 in the Korean Intellectual Property Office, the contents of which in its entirety are herein incorporated by reference.

### TECHNICAL FIELD

The present disclosure relates to a semiconductor memory device and a method for fabricating the same. More specifically, the present disclosure relates to a semiconductor memory device including a vertical channel transistor (VCT) and a method for fabricating the same.

### BACKGROUND

A semiconductor device with improved degree of integration is required to satisfy excellent performance and low price required by consumers. In the case of the semiconductor memory device, because the degree of integration is an important factor in determining the price of a product, a high degree of integration is particularly required.

In the case of a two-dimensional or planar semiconductor memory device, the degree of integration is mainly determined by an area occupied by unit memory cells, and is therefore greatly affected by the level of fine pattern forming technology. However, the increase in integration of the two-dimensional semiconductor memory device is limiting because of costs to miniaturize the pattern.

### SUMMARY

Aspects of the present disclosure provide a semiconductor memory device including a vertical channel transistor having channels extending in a vertical direction.

Aspects of the present disclosure also provide a semiconductor memory device with improved performance and degree of integration.

Aspects of the present disclosure also provide a method for fabricating a semiconductor memory device with improved performance and degree of integration.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided a semiconductor memory device comprising an active pattern which includes a first portion and a second portion connected along a vertical direction, a conductive line which is connected to the active pattern on a lower surface of the active pattern, and extends in a first horizontal direction intersecting the vertical direction, a first gate pattern which extends in a second horizontal direction intersecting the vertical direction and the first horizontal direction on a side face of the first portion of the active pattern, a second gate pattern which is spaced apart from the first gate pattern on a side face of the second portion of the active pattern, and extends in the second horizontal direction, and a data storage structure which is connected to the active pattern on an upper surface of the active pattern.

According to another aspect of the present disclosure, there is provided a semiconductor memory device comprising an active pattern which extends in a vertical direction, a conductive line which is connected to the active pattern, and extends in a first horizontal direction intersecting the vertical direction, on a lower surface of the active pattern, a gate structure which includes a plurality of gate patterns disposed at different levels from each other in the vertical direction and spaced apart from each other, on a side face of the active pattern, each of the gate patterns extending in a second horizontal direction intersecting the vertical direction and the first horizontal direction, and a data storage structure which is connected to the active pattern on an upper surface of the active pattern.

According to still another aspect of the present disclosure, there is provided a semiconductor memory device comprising an active pattern which includes a first portion and a second portion connected along a vertical direction, and includes a first side face and a second side face opposite to each other in a first horizontal direction intersecting the vertical direction, a conductive line which is connected to the active pattern on a lower surface of the active pattern, and extends in the first horizontal direction, a first gate pattern which extends in a second horizontal direction intersecting the vertical direction and the first horizontal direction, on the first side face of the first portion, a second gate pattern which extends in a second horizontal direction on the second side face of the second portion, and a data storage structure which is connected to the active pattern on an upper surface of the active pattern.

The specific details of other implementations are included in the detailed description and drawings.

### BRIEF DESCRIPTION OF DRAWINGS

The above and other aspects and features of the present disclosure will become more apparent by describing in detail implementations thereof with reference to the attached drawings.

FIG. 1 is an example layout diagram for explaining a semiconductor memory device according to some implementations.

FIG. 2 is a cross-sectional view taken along A-A of FIG. 1.

FIG. 3 is a cross-sectional view taken along B-B of FIG. 1.

FIGS. 4a, 4b, 4c and 4d are diagrams for explaining an example operation of the semiconductor memory device of FIGS. 1 to 3.

FIG. 5 is a cross-sectional view for explaining a semiconductor memory device according to some implementations.

FIG. 6 is a cross-sectional view for explaining a semiconductor memory device according to some implementations.

FIGS. 7a, 7b and 7c are diagrams for explaining an example operation of the semiconductor memory device of FIG. 6.

FIG. 8 is a cross-sectional view for explaining a semiconductor memory device according to some implementations.

FIG. 9 is a cross-sectional view for explaining a semiconductor memory device according to some implementations.

FIGS. 10a and 10b are diagrams for explaining an example operation of the semiconductor memory device of FIG. 9.

FIG. 11 is a cross-sectional view for explaining a semiconductor memory device according to some implementations.

FIGS. 12a and 12b are diagrams for explaining an example operation of the semiconductor memory device of FIG. 11.

FIG. 13 is an example layout diagram for explaining a semiconductor memory device according to some implementations.

FIGS. 14 and 15 are various cross-sectional views taken along C-C of FIG. 13.

FIG. 16 is a schematic layout diagram for explaining a semiconductor memory device according to some implementations.

FIG. 17 is a cross-sectional view taken along line D-D of FIG. 16.

FIG. 18 is a cross-sectional view taken along line E-E of FIG. 16.

FIGS. 19 to 28 are intermediate stage diagrams for explaining an example method for fabricating the semiconductor memory device according to some implementations.

### DETAILED DESCRIPTION

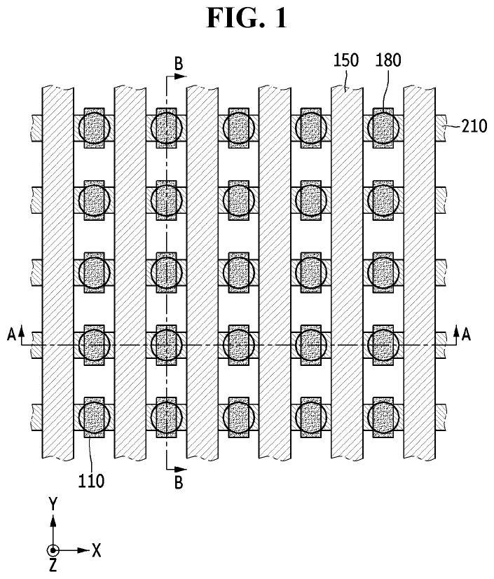

Hereinafter, a semiconductor memory device according to example implementations will be described with reference to FIGS. 1 to 18.

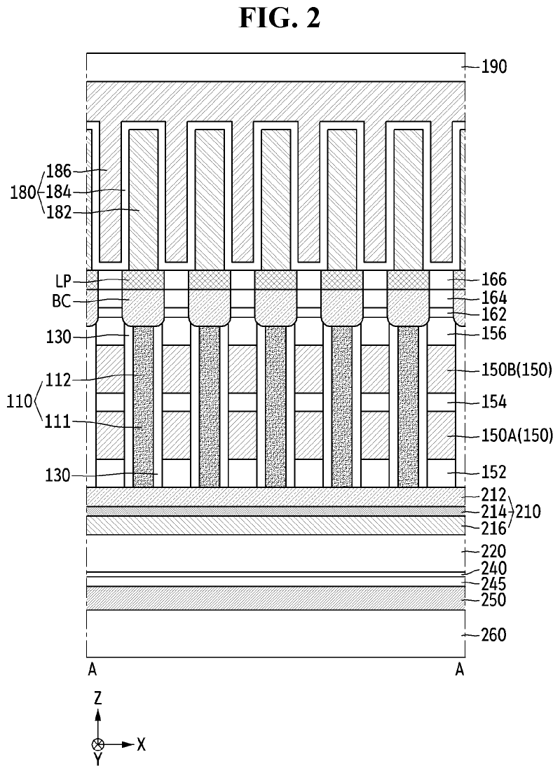

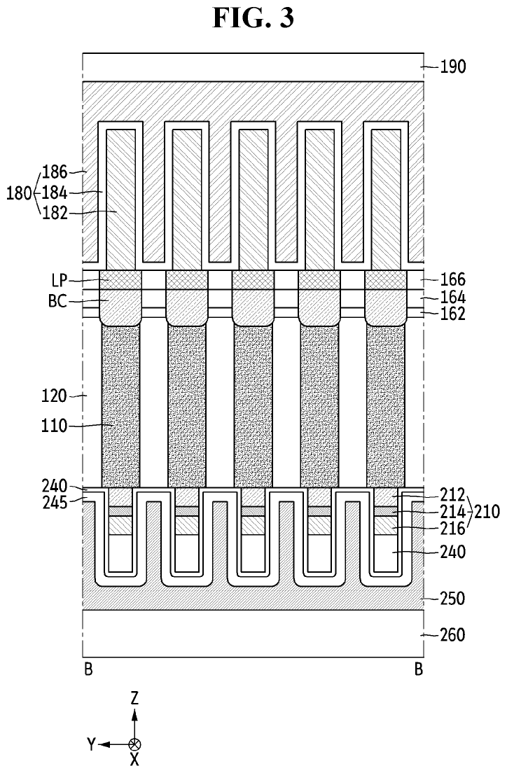

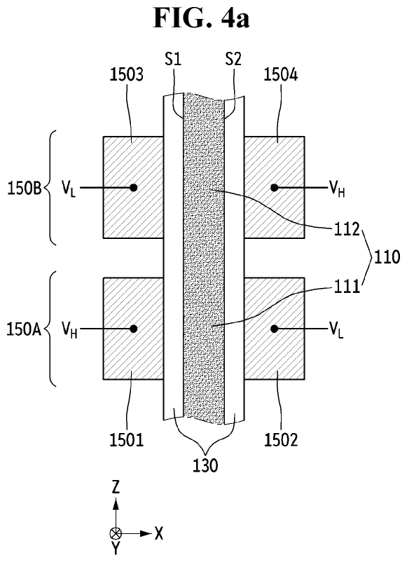

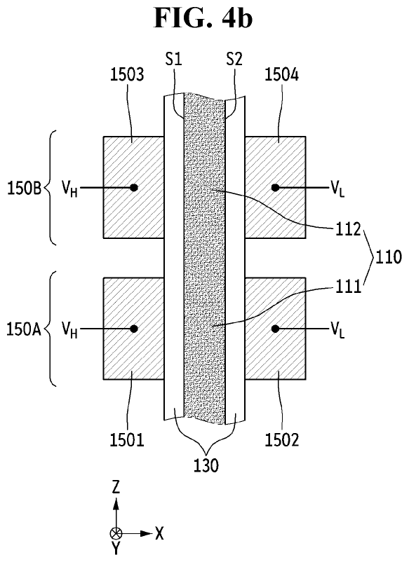

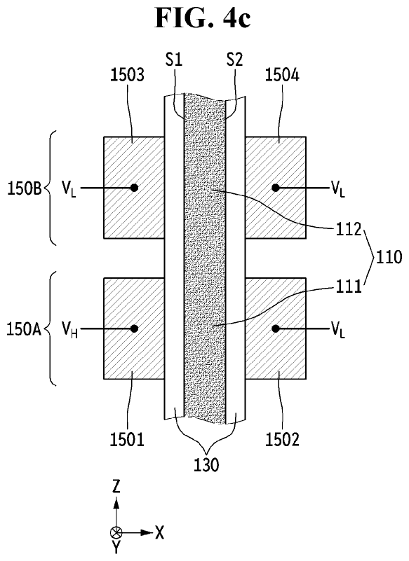

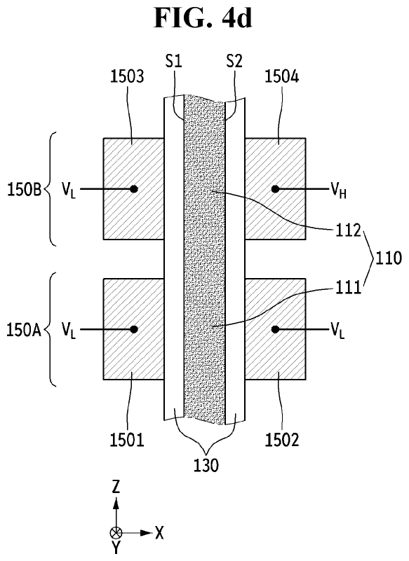

FIG. 1 is an example layout diagram for explaining a semiconductor memory device according to some implementations. FIG. 2 is a cross-sectional view taken along A-A of FIG. 1. FIG. 3 is a cross-sectional view taken along B-B of FIG. 1. FIGS. 4a, 4b, 4c and 4d are diagrams for explaining an example operation of the semiconductor memory device of FIGS. 1 to 3.

Referring to FIGS. 1 to 3, the semiconductor memory device according to some implementations includes a plurality of active patterns 110, a gate dielectric film 130, a gate structure 150, a lower spacer 152, an intermediate spacer 154, an upper spacer 156, a contact pattern BC, a landing pad LP, a data storage structure 180, an upper insulating film 190, a conductive line 210, a capping film 220, a liner film 240, a spacer film 245, a shield conductive film 250, and a lower insulating film 260.

The plurality of active patterns 110 may be arranged two-dimensionally along a horizontal plane. For example, the active patterns 110 may be arranged in a matrix shape along a first horizontal direction X and a second horizontal direction Y that intersect each other.

Each active pattern 110 may extend in a vertical direction Z that intersects the horizontal plane. For example, each active pattern 110 may extend lengthwise in the vertical direction Z that intersects the first horizontal direction X and the second horizontal direction Y. A height of each active pattern 110 extending in the vertical direction Z may be greater than a width of each active pattern 110 (e.g., a width in the first horizontal direction X and/or a width in the second horizontal direction Y). The height of each active pattern 110 may be, but is not limited to, about two to about ten times the width of each active pattern 110. Each active pattern 110 may be provided as a channel region of a vertical channel transistor (VCT). The vertical channel transistor may refer to a structure having a channel length extending in the vertical direction Z. As used herein, “extending” includes “being elongated” or “being oriented along.” For example, “extending in the vertical direction Z” includes “being elongated in the vertical direction Z” or “being oriented along the vertical direction Z.”

Each of the active patterns 110 may include a semiconductor material. For example, each of the active patterns 110 may include an elemental semiconductor material, such as monocrystalline silicon (monocrystalline Si), polycrystalline silicon (polycrystalline Si), amorphous silicon (amorphous Si), silicon germanium (SiGe), silicon germanium on insulator (SGOI), indium antimonide, lead telluride, indium arsenide, indium phosphide, gallium arsenide or gallium antimonide. Alternatively, for example, each of the active patterns 110 may include a metal oxide semiconductor material, such as indium gallium zinc oxide (IGZO) or indium tin zinc oxide (ITZO).

Each of the active patterns 110 may include a single layer or multiple layers of the semiconductor material. In some implementations, each of the active patterns 110 may include a single crystal semiconductor material. As an example, each of the active patterns 110 may include monocrystalline silicon.

In some implementations, each of the active patterns 110 may include a first portion 111 and a second portion 112 that are connected along the vertical direction Z. For example, as shown in FIGS. 2 and 3, the first portion 111 may be a lower portion of each active pattern 110, and the second portion 112 may be an upper portion of each active pattern 110. The first portion 111 and the second portion 112 may be connected in the vertical direction Z to form an integral semiconductor pattern (e.g., an integral silicon pattern).

In some implementations, the active patterns 110 arranged along the second horizontal direction Y may be separated from each other by a first interlayer insulating film 120. For example, as shown in FIG. 3, the active patterns 110 and the first interlayer insulating film 120 may be arranged alternately along the second horizontal direction Y.

The first interlayer insulating film 120 may include, but is not limited to, at least one of, for example, silicon oxide, silicon nitride, silicon oxynitride, silicon oxycarbonitride or a combination thereof. As an example, the first interlayer insulating film 120 may include a silicon oxide film. The first interlayer insulating film 120 may be a single film made of one type of insulating material, or a multi-layer film made of a combination of several types of insulating materials.

The gate dielectric film 130 may be interposed between each active pattern 110 and the gate structure 150. For example, the gate dielectric film 130 may conformally extend along the profile of the side faces of each active pattern 110. In some implementations, the gate dielectric film 130 may be formed on the side faces of each active pattern 110 that intersect the first horizontal direction X. In some implementations, the gate dielectric film 130 may extend lengthwise in the second horizontal direction Y. In some implementations, the gate dielectric film 130 may not be formed on the side faces of each active pattern 110 that intersect the second horizontal direction Y.

The gate dielectric film 130 may include, for example, but is not limited to, at least one of a silicon oxide, a silicon oxynitride, a high dielectric constant (high-k) material having a higher dielectric constant than the silicon oxide, or a combination thereof. The high dielectric constant material may include, but is not limited to, a metal oxide or a metal oxynitride, for example, at least one of hafnium dioxide (HfO₂), hafnium silicate (HfSiO), hafnium silicon oxynitride (HfSiON), hafnium tantalum oxide (HfTaO), hafnium titanium oxide (HfTiO), hafnium zirconium oxide (HfZrO), zirconium dioxide (ZrO₂), aluminum oxide (Al₂O₃) or a combination thereof.

A gate structure 150 may be disposed on the side faces of each active pattern 110. The gate structure 150 may be spaced apart from each active pattern 110 by a gate dielectric film 130. The gate structure 150 may intersect each active pattern 110. For example, the gate structure 150 may extend lengthwise in the second horizontal direction Y. The plurality of gate structures 150 may be spaced apart from each other in the first horizontal direction X, and extend side by side (or parallel) in the second horizontal direction Y. Each gate structure 150 may extend parallel to a row of active patterns 110 arranged along the second horizontal direction Y. The gate structures 150 may be provided as word lines of the semiconductor memory device according to some implementations.

In some implementations, the gate structure 150 may include a plurality of gate patterns 150A and 150B that are disposed at different levels in the vertical direction Z and spaced apart from each other. Here, the expression “disposed at different levels” means disposition at different heights in the vertical direction Z on the basis of a lower surface of each active pattern 110. For example, the gate structure 150 may include a first gate pattern 150A and a second gate pattern 150B that are spaced apart from each other. The first gate pattern 150A and the second gate pattern 150B may each extend lengthwise in the second horizontal direction Y. The first gate pattern 150A may intersect the first portion 111 of each active pattern 110. The second gate pattern 150B may intersect the second portion 112 of each active pattern 110.

In some implementations, the first gate pattern 150A and the second gate pattern 150B may overlap in the vertical direction Z. For example, the first gate pattern 150A and the second gate pattern 150B may be arranged in sequence along the vertical direction Z. The first gate pattern 150A and the second gate pattern 150B may be spaced apart from each other in the vertical direction Z.

The gate structure 150 may include a conductive material, for example, at least one of doped polysilicon, metal, conductive metal nitride, conductive metal silicide, conductive metal oxide, or a combination thereof. For example, the gate structure 150 may include, but is not limited to, at least one of doped polysilicon, aluminum (Al), copper (Cu), titanium (Ti), tantalum (Ta), ruthenium (Ru), tungsten (W), molybdenum (Mo), platinum (Pt), nickel (Ni), cobalt (Co), titanium nitride (TiN), tantalum nitride (TaN), tungsten nitride (WN), niobium nitride (NbN), titanium aluminide (TiAl), titanium aluminum nitride (TiAlN), titanium silicide (TiSi), titanium silicon nitride (TiSiN), tantalum silicide (TaSi), tantalum silicon nitride (TaSiN), ruthenium titanium nitride (RuTiN), nickel silicide (NiSi), cobalt silicide (CoSi), iridium oxide (IrOₓ), ruthenium oxide (RuOₓ), or a combination thereof.

The plurality of gate patterns 150A and 150B may be configured to be applied with voltages independently of each other. For example, a circuit (e.g., a processor) electrically connected to the plurality of gate patterns 150A and 150B may be configured to apply different voltages to the first gate pattern 150A and the second gate pattern 150B. Thus, the first gate pattern 150A and the second gate pattern 150B may form channels in each active pattern 110 independently of each other.

The lower spacer 152 may be formed on the lower surface of the gate structure 150. The lower spacer 152 may be interposed between the conductive line 210 and the gate structure 150. The gate structure 150 may be spaced apart from the conductive line 210 in the vertical direction Z by the lower spacer 152. The upper surface of the lower spacer 152 may be disposed to be higher than the lower surface of each active pattern 110 in the vertical direction Z. That is, the lower surface of the gate structure 150 may be located to be higher than the lower surface of each active pattern 110 in the vertical direction Z. In some implementations, the lower surface of the lower spacer 152 may be disposed to be coplanar with the lower surface of each active pattern 110. In some implementations, a part of the gate dielectric film 130 may be interposed between each active pattern 110 and the lower spacer 152.

The lower spacer 152 may include an insulating material, for example, but is not limited to, at least one of silicon oxide, silicon nitride, silicon oxynitride, silicon oxycarbonitride or a combination thereof. As an example, the lower spacer 152 may include a silicon nitride film. The lower spacer 152 may be a single film made of one type of insulating material, or a multi-layer film made of a combination of several types of insulating materials.

The intermediate spacer 154 may be interposed between the lower spacer 152 and the upper spacer 156 in the vertical direction Z. The intermediate spacer 154 may cover an upper surface of the first gate pattern 150A. The second gate pattern 150B may be formed on an upper surface of the intermediate spacer 154. In some implementations, a part of the gate dielectric film 130 may be interposed between each active pattern 110 and the intermediate spacer 154.

In some implementations, the intermediate spacer 154 may be interposed between the first gate pattern 150A and the second gate pattern 150B in the vertical direction Z. The first gate pattern 150A and the second gate pattern 150B may be separated in the vertical direction Z by the intermediate spacer 154.

The intermediate spacer 154 may include, for example, but is not limited to, at least one of silicon oxide, silicon nitride, silicon oxynitride, silicon oxycarbonitride or a combination thereof. As an example, the intermediate spacer 154 may include a silicon oxide film. The intermediate spacer 154 may be a single film made of one type of insulating material, or may be a multi-layer film made of a combination of several types of insulating materials.

The upper spacer 156 may be formed on the upper surface of the gate structure 150. The upper spacer 156 may be interposed between the gate structure 150 and the contact pattern BC and/or between the gate structure 150 and an etching stop film 162. The gate structure 150 may be spaced apart from the contact pattern BC and/or the etching stop film 162 in the vertical direction Z by the upper spacer 156. In the vertical direction Z, the lower surface of the upper spacer 156 may be located to be lower than the upper surface of each active pattern 110. That is, in the vertical direction Z, the upper surface of the gate structure 150 may be located to be lower than the upper surface of each active pattern 110. In some implementations, a part of the gate dielectric film 130 may be interposed between each active pattern 110 and the upper spacer 156.

The upper spacer 156 may include an insulating material, for example, but is not limited to, at least one of silicon oxide, silicon nitride, silicon oxynitride, silicon oxycarbonitride or a combination thereof. As an example, the upper spacer 156 may include a silicon nitride film. The upper spacer 156 may be a single film made of one type of insulating material, or may be a multi-layer film made of a combination of several types of insulating materials.

The contact pattern BC may be disposed on the upper surface of each active pattern 110. The contact pattern BC may be connected to each active pattern 110. For example, the etching stop film 162 and the second interlayer insulating film 164 may be sequentially stacked on the upper surfaces of the active patterns 110, the upper surface of the first interlayer insulating film 120, and the upper surface of the upper spacer 156. The contact pattern BC penetrates the etching stop film 162 and the second interlayer insulating film 164, and may be brought into contact with the upper surfaces of each active pattern 110.

The contact pattern BC may include a conductive material, for example, but is not limited to, at least one of polysilicon doped with impurities, conductive metal nitride, conductive metal silicon nitride, metal carbonitride, conductive metal silicide, conductive metal oxide, a two-dimensional material, a metal or a combination thereof. As an example, the contact pattern BC may include a polysilicon film doped with n-type impurities (e.g., P, Sb, or As).

The landing pad LP may be disposed on the upper surface of the contact pattern BC. The landing pad LP may be connected to the contact pattern BC. For example, a third interlayer insulating film 166 may be stacked on an upper surface of the second interlayer insulating film 164. The landing pad LP may penetrate the third interlayer insulating film 166, and be brought into contact with an upper surface of the contact pattern BC.

The landing pad LP may include a conductive material, for example, but is not limited to, at least one of doped polysilicon, conductive metal nitride, conductive metal silicon nitride, metal carbonitride, conductive metal silicide, conductive metal oxide, a two-dimensional material, a metal or a combination thereof. As an example, the landing pad LP may include a tungsten (W) film.

The data storage structure 180 may be disposed on the upper surface of the landing pad LP and the upper surface of the third interlayer insulating film 166. The data storage structure 180 may be connected to the landing pad LP. The data storage structure 180 may be electrically connected to the active patterns 110 through the contact pattern BC and the landing pad LP. The data storage structure 180 is controlled by a conductive line 210 provided as a bit line and a gate structure 150 provided as a word line, and may store data in a unit memory cell corresponding to each active pattern 110.

In some implementations, the data storage structure 180 may be a capacitor. For example, the data storage structure 180 may include a lower electrode 182, a capacitor dielectric film 184, and an upper electrode 186, which are sequentially stacked on the landing pad LP. The data storage structure 180 may store charges inside the capacitor dielectric film 184, using a potential difference generated between the lower electrode 182 and the upper electrode 186.

Each of the lower electrode 182 and the upper electrode 186 may include a conductive material, for example, but is not limited to, doped polysilicon, a metal, a metal nitride or the like. The capacitor dielectric film 184 may include, for example, but is not limited to, silicon oxide or a high dielectric constant material.

The upper insulating film 190 may be stacked on the data storage structure 180. The upper insulating film 190 may cover at least a part of the data storage structure 180. The upper insulating film 190 may include, for example, but is not limited to, at least one of silicon oxide, silicon nitride, silicon oxynitride, silicon oxycarbonitride or a combination thereof.

The conductive line 210 may be disposed on the lower surface of each active pattern 110. The conductive lines 210 may intersect the gate structures 150. For example, the conductive lines 210 may extend lengthwise in the first horizontal direction X. The plurality of conductive lines 210 may be spaced apart from each other in the second horizontal direction Y and extend side by side (or parallel) in the first horizontal direction X. Each conductive line 210 may be commonly connected to a row of active patterns 110 arranged along the first horizontal direction X. The conductive lines 210 may be provided as bit lines of the semiconductor memory device according to some implementations.

In some implementations, the conductive line 210 may include a first conductive film 212, a second conductive film 214, and a third conductive film 216 which are sequentially stacked on the lower surface of each active pattern 110. Each of the first conductive film 212, the second conductive film 214, and the third conductive film 216 may include a conductive material, for example, but is not limited to, at least one of polysilicon doped with impurities, TiN, TiSiN, tungsten, tungsten silicide, molybdenum or a combination thereof. As an example, the first conductive film 212 may include a polysilicon film doped with n-type impurities (e.g., P, Sb or As), the second conductive film 214 may include a TiSiN film or WSiN, and the third conductive film 216 may include a tungsten (W) film or molybdenum.

The capping film 220 may extend along a lower surface of the conductive line 210. The capping film 220 may extend lengthwise in the first horizontal direction X. The capping film 220 may include an insulating material, for example, but is not limited to, at least one of silicon oxide, silicon nitride, silicon oxynitride, silicon oxycarbonitride and a combination thereof. As an example, the capping film 220 may include a silicon nitride film.

The liner film 240 may be stacked under the conductive line 210 and the capping film 220. For example, the liner film 240 may extend conformally along the profile of the side face and lower surface of the capping film 220, the side face of the conductive line 210, the lower surface of the lower spacer 152, and the lower surface of the first interlayer insulating film 120.

The liner film 240 may include an insulating material, for example, but is not limited to, at least one of silicon oxide, silicon nitride, silicon oxynitride, silicon oxycarbonitride and a combination thereof. As an example, the liner film 240 may include a silicon nitride film.

The spacer film 245 may be stacked under the liner film 240. For example, the spacer film 245 may conformally extend along the profile of the side face and lower surface of the liner film 240.

The spacer film 245 may include an insulating material, for example, but is not limited to, at least one of silicon oxide, silicon nitride, silicon oxynitride, silicon oxycarbonitride and a combination thereof. As an example, the spacer film 245 may include a silicon oxide film.

The shield conductive film 250 may be stacked under the spacer film 245. At least a part of the shield conductive film 250 may be interposed between the conductive lines 210 arranged along the second horizontal direction Y. For example, as shown in FIG. 3, the shield conductive film 250 may be formed to fill at least a part of the region between one conductive line 210 and the other conductive line 210. The shield conductive film 250 may be separated from the conductive lines 210 by the liner film 240 and/or the spacer film 245.

The shield conductive film 250 may include a conductive material, for example, but is not limited to, at least one of doped polysilicon, a metal, a conductive metal nitride, a conductive metal silicide, a conductive metal oxide or a combination thereof. The shield conductive film 250 may be configured to be applied with a predetermined bias voltage (e.g., a ground voltage). For example, a circuit (e.g., a processor) may be configured to apply a predetermined bias voltage (e.g., a ground voltage) to the shield conductive film 250. Accordingly, the shield conductive film 250 may reduce a coupling noise between the conductive lines 210 in the second horizontal direction Y.

The lower insulating film 260 may be stacked under the shield conductive film 250. The lower insulating film 260 may cover at least a part of the shield conductive film 250. The lower insulating film 260 may include, for example, but is not limited to, at least one of silicon oxide, silicon nitride, silicon oxynitride, silicon oxycarbonitride or a combination thereof.

Referring to FIGS. 4a to 4d, for each active pattern 110, the first gate pattern 150A may include a first gate electrode 1501 and a second gate electrode 1502, and the second gate pattern 150B may include a third gate electrode 1503 and a fourth gate electrode 1504.

Each active pattern 110 may include a first side face S1 and a second side face S2 that are opposite to each other in the first horizontal direction X. The first gate electrode 1501 may be disposed on the first side face S1 of the first portion 111, and the second gate electrode 1502 is disposed on the second side face S2 of the first portion 111. The third gate electrode 1503 may be disposed on the first side face S1 of the second portion 112, and the fourth gate electrode 1504 may be disposed on the second side face S2 of the second portion 112. The first to fourth gate electrodes 1501 to 1504 may be configured to be applied with voltages independently of each other.

When a high level voltage V_{H} equal to or higher than a threshold voltage is applied to at least a part of the first gate pattern 150A and at least a part of the second gate pattern 150B for each active pattern 110, the corresponding vertical channel transistor may be provided in an on-state.

As an example, as shown in FIG. 4a, the high level voltage V_{H} may be applied to each of the first and fourth gate electrodes 1501 and 1504, and a low level voltage V_{L} may be applied to each of the second and third gate electrodes 1502 and 1503. In such a case, the first portion 111 may form a channel by the first gate electrode 1501, and the second portion 112 may form a channel by the fourth gate electrode 1504. As a result, the vertical channel transistor may be turned on.

As another example, as shown in FIG. 4b, the high level voltage V_{H} may be applied to each of the first and third gate electrodes 1501 and 1503, and the low level voltage V_{L} may be applied to each of the second and fourth gate electrodes 1502 and 1504. In such a case, the first portion 111 may form a channel by the first gate electrode 1501, and the second portion 112 may form a channel by the third gate electrode 1503. Accordingly, the vertical channel transistor may be turned on.

When the low level voltage V_{L} equal to or lower than the threshold voltage is applied to at least one of the first gate pattern 150A or the second gate pattern 150B for each active pattern 110, the corresponding vertical channel transistor VCT may be provided in an off-state.

As an example, as shown in FIG. 4c, the high level voltage VH may be applied to the first gate electrode 1501, and the low level voltage V_{L} may be applied to each of the second to fourth gate electrodes 1502 to 1504. In such a case, the first portion 111 may form a channel by the first gate electrode 1501, but the second portion 112 may not form a channel. Accordingly, the vertical channel transistor may be turned off.

As another example, as shown in FIG. 4d, the high level voltage V_{H} may be applied to the fourth gate electrode 1504, and the low level voltage V_{L} may be applied to each of the first to third gate electrodes 1501 to 1503. In such a case, the second portion 112 may form a channel by the fourth gate electrode 1504, but the first portion 111 may not form a channel. Accordingly, the vertical channel transistor may be turned off.

In some implementations, each active pattern 110 may be controlled by a pair of first and second gate patterns 150A and 150B arranged along a diagonal direction between the first horizontal direction X and the vertical direction Z. As an example, each active pattern 110 may be configured to be controlled by the first and fourth gate electrodes 1501 and 1504. As another example, each active pattern 110 may be configured to be controlled by the second gate electrode 1502 and the third gate electrode 1503.

As the degree of integration of the semiconductor memory device including the vertical channel transistor (VCT) continues to increase, the coupling noise between adjacent word lines in the horizontal direction has become a problem. For example, two word lines opposite to each other in the horizontal direction may be provided between adjacent active patterns. However, as the degree of integration of the semiconductor memory device continues to increase in the horizontal direction, interference between channels controlled by the two word lines has intensified.

The semiconductor memory device according to some implementations may reduce the coupling noise between the word lines in the first horizontal direction X, by including a plurality of gate patterns 150A and 150B disposed at different levels in the vertical direction Z. Specifically, as explained above, the first gate pattern 150A may be configured to control the first portion 111 of each active pattern 110, and the second gate pattern 150B may be configured to control the second portion 112 of each active pattern 110. In such a case, a wide pitch between the word lines in the first horizontal direction X may be provided. Also, each active pattern 110 may be effectively controlled according to the voltages applied independently to each of the first gate pattern 150A and the second gate pattern 150B. Accordingly, it is possible to provide a semiconductor memory device with improved performance and degree of integration.

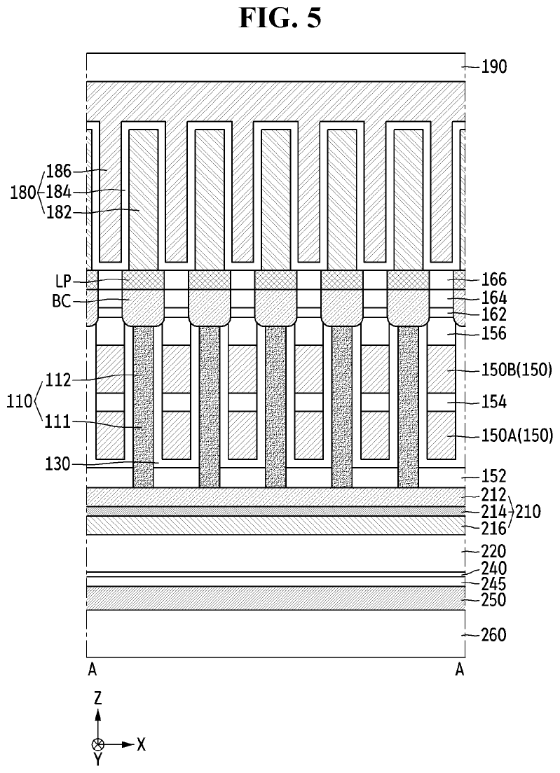

FIG. 5 is a cross-sectional view for explaining a semiconductor memory device according to some implementations. For convenience of explanation, repeated parts of those explained above using FIGS. 1 to 4d will be briefly explained or omitted.

With reference to FIGS. 1 and 5, in the semiconductor device according to some implementations, a part of the gate dielectric film 130 is interposed between the lower spacer 152 and the gate structure 150.

For example, the gate dielectric film 130 may conformally extend along the profile of the side face of each active pattern 110 and the upper surface of the lower spacer 152. The gate structure 150 may be stacked on the upper surface of the gate dielectric film 130.

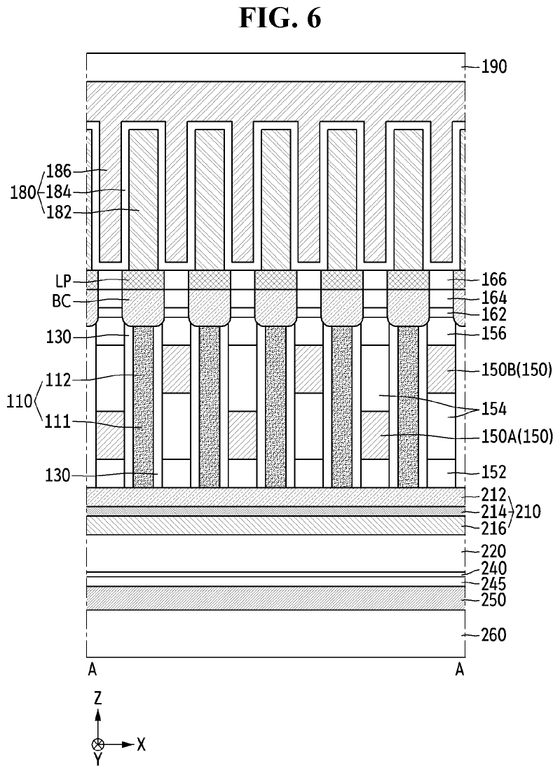

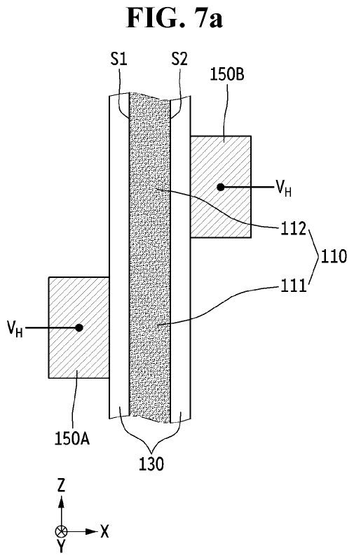

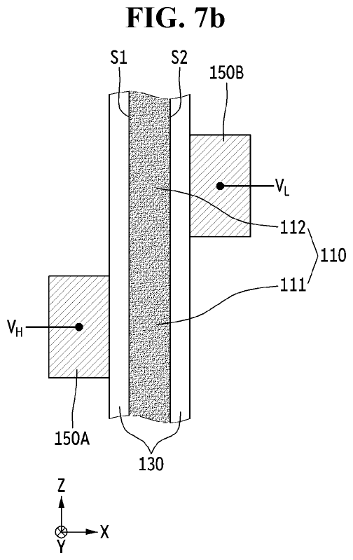

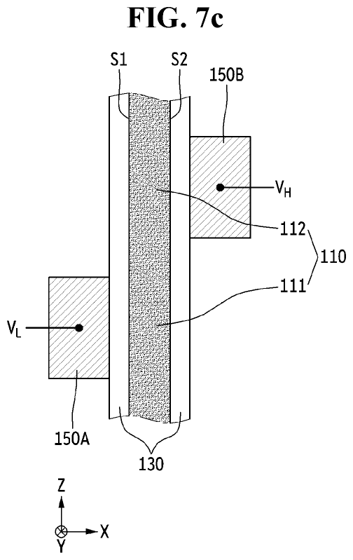

FIG. 6 is a cross-sectional view for explaining a semiconductor memory device according to some implementations. FIGS. 7a, 7b and 7c are diagrams for explaining an example operation of the semiconductor memory device of FIG. 6. For convenience of explanation, repeated parts of those explained above using FIGS. 1 to 5 will be briefly explained or omitted.

Referring to FIGS. 1 and 6, in the semiconductor device according to some implementations, the second gate pattern 150B does not overlap the first gate pattern 150A in the vertical direction Z.

For example, the pair of the first gate pattern 150A and the second gate pattern 150B may be arranged along a diagonal direction between the first horizontal direction X and the vertical direction Z. The pair of the first gate pattern 150A and the second gate pattern 150B may be repeatedly arranged along the first horizontal direction X.

In some implementations, the first gate pattern 150A and the second gate pattern 150B may not overlap in the first horizontal direction X. For example, an upper surface of the first gate pattern 150A may be located to be lower than a lower surface of the second gate pattern 150B in the vertical direction Z. In such a case, interference between the first gate pattern 150A and the second gate pattern 150B may be reduced.

Referring to FIGS. 7a to 7c, for each active pattern 110, the first gate pattern 150A may be disposed on the first side face S1 of the first portion 111, but may not be disposed on the second side face S2 of the first portion 111. In addition, the second gate pattern 150B may be disposed on the second side face S2 of the second portion 112, but may not be disposed on the first side face S1 of the second portion 112. The first gate pattern 150A and the second gate pattern 150B may be configured to be applied with voltages independently of each other.

When the high level voltage V_{H} equal to or higher than the threshold voltage is applied to both the first gate pattern 150A and the second gate pattern 150B for each active pattern 110, the corresponding vertical channel transistor may be provided in an on-state.

As an example, as shown in FIG. 7a, the high level voltage V_{H} may be applied to each of the first gate pattern 150A and the second gate pattern 150B. In such a case, the first portion 111 may form a channel by the first gate pattern 150A, and the second portion 112 may form a channel by the second gate pattern 150B. Accordingly, the vertical channel transistor may be turned on.

For each active pattern 110, when the low level voltage V_{L} equal to or lower than the threshold voltage is applied to at least one of the first gate pattern 150A and the second gate pattern 150B, the corresponding vertical channel transistor VCT may be provided in an off-state.

As an example, as shown in FIG. 7b, the high level voltage V_{H} may be applied to the first gate pattern 150A, and the low level voltage V_{L} may be applied to the second gate pattern 150B. In such a case, the first portion 111 may form a channel by the first gate pattern 150A, but the second portion 112 may not form a channel. Accordingly, the vertical channel transistor may be turned off.

As another example, as shown in FIG. 7c, the low level voltage V_{L} may be applied to the first gate pattern 150A, and the high level voltage V_{H} may be applied to the second gate pattern 150B. In such a case, the second portion 112 may form a channel by the second gate pattern 150B, but the first portion 111 may not form a channel. Accordingly, the vertical channel transistor may be turned off.

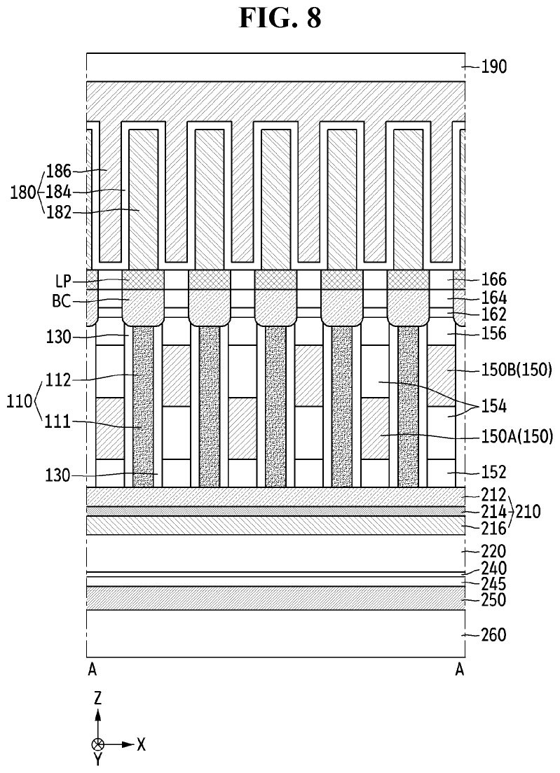

FIG. 8 is a cross-sectional view for explaining a semiconductor memory device according to some implementations. For convenience of explanation, repeated parts of those explained above using FIGS. 1 to 7c will be briefly explained or omitted.

Referring to FIGS. 1 and 8, in the semiconductor device according to some implementations, a part of the first gate pattern 150A and a part of the second gate pattern 150B overlap in the first horizontal direction X.

For example, the upper surface of the first gate pattern 150A may be located to be higher than the lower surface of the second gate pattern 150B in the vertical direction Z. In such a case, the gate controllability of the gate structure 150 for each active pattern 110 may be improved.

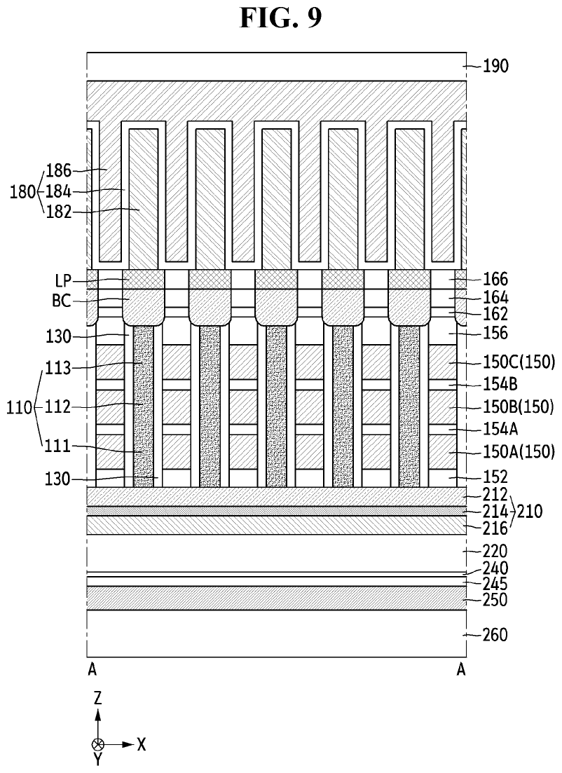

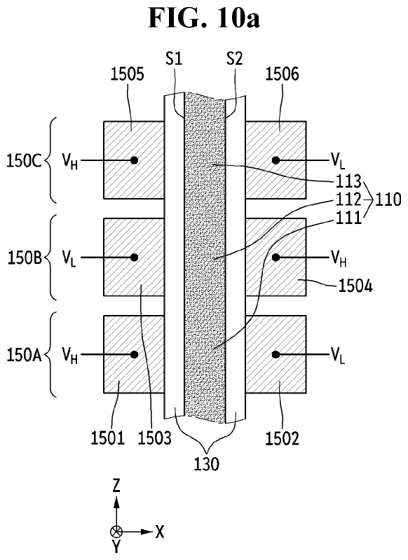

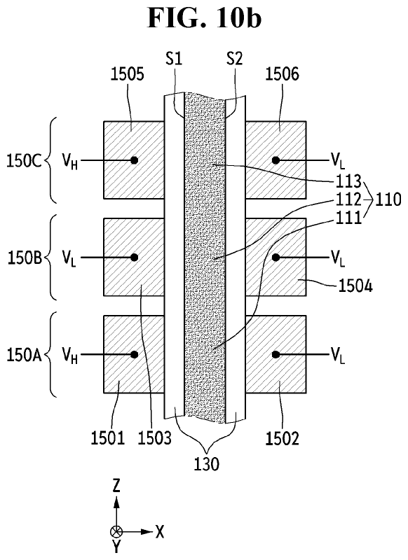

FIG. 9 is a cross-sectional view for explaining a semiconductor memory device according to some implementations. FIGS. 10a and 10b are diagrams for explaining an example operation of the semiconductor memory device of FIG. 9. For convenience of explanation, repeated parts of those explained above using FIGS. 1 to 8 will be briefly explained or omitted.

With reference to FIGS. 1 and 9, in the semiconductor device according to some implementations, each active pattern 110 includes a first portion 111, a second portion 112, and a third portion 113 that are connected along the vertical direction Z.

For example, the first portion 111 may be a lower portion of each active pattern 110, the second portion 112 may be a central portion of each active pattern 110, and the third portion 113 may be an upper portion of each active pattern 110. The first portion 111, the second portion 112, and the third portion 113 may be connected in the vertical direction Z to form an integral semiconductor pattern (e.g., an integral silicon pattern).

The gate structure 150 may include a plurality of gate patterns 150A to 150C which are disposed at different levels in the vertical direction Z and spaced apart from each other. For example, the gate structure 150 may include a first gate pattern 150A, a second gate pattern 150B, and a third gate pattern 150C that are spaced apart from each other. Each of the first gate pattern 150A, the second gate pattern 150B, and the third gate pattern 150C may extend lengthwise in the second horizontal direction Y. The first gate pattern 150A may intersect the first portion 111 of each active pattern 110. The second gate pattern 150B may intersect the second portion 112 of each active pattern 110. The third gate pattern 150C may intersect the third portion 113 of each active pattern 110.

In some implementations, the first gate pattern 150A, the second gate pattern 150B, and the third gate pattern 150C may overlap in the vertical direction Z. For example, the first gate pattern 150A, the second gate pattern 150B, and the third gate pattern 150C may be arranged in sequence along the vertical direction Z. The first gate pattern 150A, the second gate pattern 150B, and the third gate pattern 150C may be spaced apart from each other in the vertical direction Z.

The plurality of gate patterns 150A to 150C may be configured to be applied with voltages independently of each other. For example, a circuit (e.g., a processor) electrically connected to the plurality of gate patterns 150A to 150C may be configured to apply different voltages to the first gate pattern 150A, the second gate pattern 150B, and the third gate pattern 150C. Thus, the first gate pattern 150A, the second gate pattern 150B, and the third gate pattern 150C may form channels inside each active pattern 110 independently of one another.

In some implementations, a first intermediate spacer 154A and a second intermediate spacer 154B may be formed between the lower spacer 152 and the upper spacer 156. The first intermediate spacer 154A may cover an upper surface of the first gate pattern 150A. The second gate pattern 150B may be formed on the upper surface of the first intermediate spacer 154A. The second intermediate spacer 154B may cover an upper surface of the second gate pattern 150B. The third gate pattern 150C may be formed on the upper surface of the second intermediate spacer 154B.

In some implementations, the first intermediate spacer 154A may be interposed between the first gate pattern 150A and the second gate pattern 150B in the vertical direction Z. The first gate pattern 150A and the second gate pattern 150B may be separated in the vertical direction Z by the first intermediate spacer 154A.

In some implementations, the second intermediate spacer 154B may be interposed between the second gate pattern 150B and the third gate pattern 150C in the vertical direction Z. The second gate pattern 150B and the third gate pattern 150C may be separated in the vertical direction Z by the second intermediate spacer 154B.

Each of the first intermediate spacer 154A and the second intermediate spacer 154B may include, for example, but are not limited to, at least one of silicon oxide, silicon nitride, silicon oxynitride, silicon oxycarbonitride or a combination thereof. As an example, each of the first intermediate spacer 154A and the second intermediate spacer 154B may include a silicon oxide film. Each of the first intermediate spacer 154A and the second intermediate spacer 154B may be a single film made of one type of insulating material, or may be a multi-layer film made of a combination of several types of insulating materials.

Referring to FIGS. 10a and 10b, for each active pattern 110, the first gate pattern 150A may include a first gate electrode 1501 and a second gate electrode 1502, the second gate pattern 150B may include a third gate electrode 1503 and a fourth gate electrode 1504, and the third gate pattern 150C may include a fifth gate electrode 1505 and a sixth gate electrode 1506.

The first gate electrode 1501 may be disposed on the first side face S1 of the first portion 111, and the second gate electrode 1502 may be disposed on the second side face S2 of the first portion 111. The third gate electrode 1503 may be disposed on the first side face S1 of the second portion 112, and the fourth gate electrode 1504 may be disposed on the second side face S2 of the second portion 112. The fifth gate electrode 1505 may be disposed on the first side face S1 of the third portion 113, and the sixth gate electrode 1506 may be disposed on the second side face S2 of the third portion 113. The first to sixth gate electrodes 1501 to 1506 may be configured to be applied with voltages independently of each other.

When the high level voltage V_{H} equal to or higher than the threshold voltage is applied to at least a part of the first gate pattern 150A, at least a part of the second gate pattern 150B, and at least a part of the third gate pattern 150C for each active pattern 110, the corresponding vertical channel transistor may be provided in an on-state.

As an example, as shown in FIG. 10a, the high level voltage V_{H} may be applied to each of the first, fourth and fifth gate electrodes 1501, 1504 and 1505, and the low level voltage V_{L} may be applied to each of the second, third and sixth gate electrodes 1502, 1503 and 1506. In such a case, the first portion 111 may form a channel by the first gate electrode 1501, the second portion 112 may form a channel by the fourth gate electrode 1504, and the third portion 113 may form a channel by the fifth gate electrode 1505. As a result, the vertical channel transistor may be turned on.

When the low level voltage V_{L} equal to or lower than the threshold voltage is applied to at least one of the first gate pattern 150A, the second gate pattern 150B, and the third gate pattern 150C for each active pattern 110, the corresponding vertical channel transistor VCT may be provided in an off-state.

As an example, as shown in FIG. 10b, the high level voltage V_{H} may be applied to each of the first and fifth gate electrodes 1501 and 1505, and the low level voltage V_{L} may be applied to each of the second, third, fourth, and sixth gate electrodes 1502, 1503, 1504 and 1506. In such a case, the first portion 111 may form a channel by the first gate electrode 1501, the third portion 113 may form a channel by the fifth gate electrode 1505, but the second portion 112 does not form a channel. Accordingly, the vertical channel transistor may be turned off.

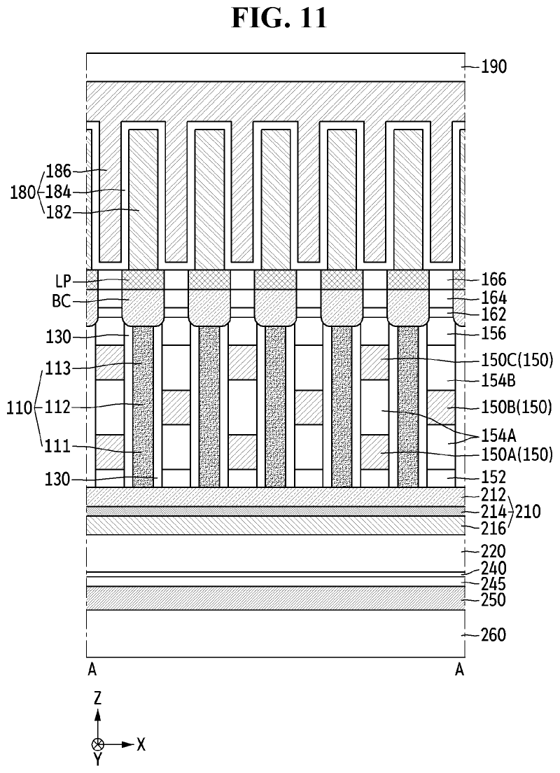

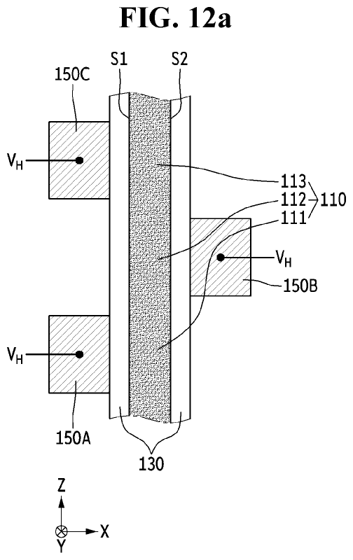

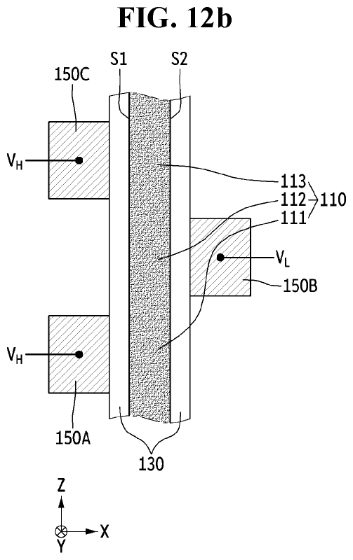

FIG. 11 is a cross-sectional view for explaining a semiconductor memory device according to some implementations. FIGS. 12a and 12b are diagrams for explaining an example operation of the semiconductor memory device of FIG. 11. For convenience of explanation, repeated parts of those explained above using FIGS. 1 to 10b will be briefly explained or omitted.

With reference to FIGS. 1 and 11, in the semiconductor device according to some implementations, the second gate pattern 150B does not overlap the first gate pattern 150A and the third gate pattern 150C in the vertical direction Z.

For example, the first gate pattern 150A and the third gate pattern 150C may overlap in the vertical direction Z. The pair of first and second gate patterns 150A and 150B may be arranged along a first diagonal direction between the first horizontal direction X and the vertical direction Z, and the pair of second and third gate patterns 150B and 150C may be arranged along a second diagonal direction between the first horizontal direction X and the vertical direction Z. The pair of first and second gate patterns 150A and 150B may be repeatedly arranged along the first horizontal direction X, and the pair of second and third gate patterns 150B and 150C may be repeatedly arranged along the first horizontal direction X.

Referring to FIGS. 12a and 12b, for each active pattern 110, the first gate pattern 150A may be disposed on the first side face S1 of the first portion 111, but may not be disposed on the second side face S2 of the first portion 111. The second gate pattern 150B may be disposed on the second side face S2 of the second portion 112, but may not be disposed on the first side face S1 of the second portion 112. The third gate pattern 150C may be disposed on the first side face S1 of the third portion 113, but may not be disposed on the second side face S2 of the third portion 113. The first gate pattern 150A, the second gate pattern 150B, and the third gate pattern 150C may be configured to be applied with voltages independently of each other.

When the high level voltage V_{H} equal to or higher than the threshold voltage is applied to all the first gate pattern 150A, the second gate pattern 150B, and the third gate pattern 150C for each active pattern 110, the corresponding vertical channel transistor VCT may be provided in an on-state.

As an example, as shown in FIG. 12a, the high level voltage V_{H} may be applied to each of the first gate pattern 150A, the second gate pattern 150B, and the third gate pattern 150C. In such a case, the first portion 111 may form a channel by the first gate pattern 150A, the second portion 112 may form a channel by the second gate pattern 150B, and the third portion 113 may form a channel by the third gate pattern 150C. Accordingly, the vertical channel transistor may be turned on.

When the lower level voltage V_{L} equal to or lower than the threshold voltage is applied to at least one of the first gate pattern 150A, the second gate pattern 150B or the third gate pattern 150C for each active pattern 110, the corresponding vertical channel transistor VCT may be provided in an off-state.

As an example, as shown in FIG. 12b, the high level voltage V_{H} may be applied to each of the first gate pattern 150A and the third gate pattern 150C, and the low level voltage V_{L} may be applied to the second gate pattern 150B. In such a case, the first portion 111 may form a channel by the first gate pattern 150A, and the third portion 113 may form a channel by the third gate pattern 150C, but the second portion 112 may not form a channel. Accordingly, the vertical channel transistor may be turned off.

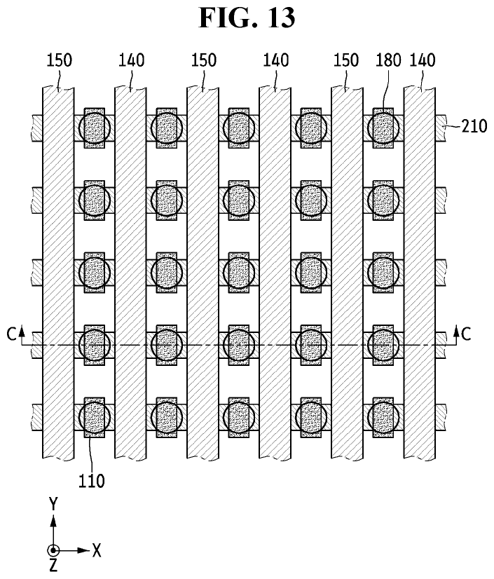

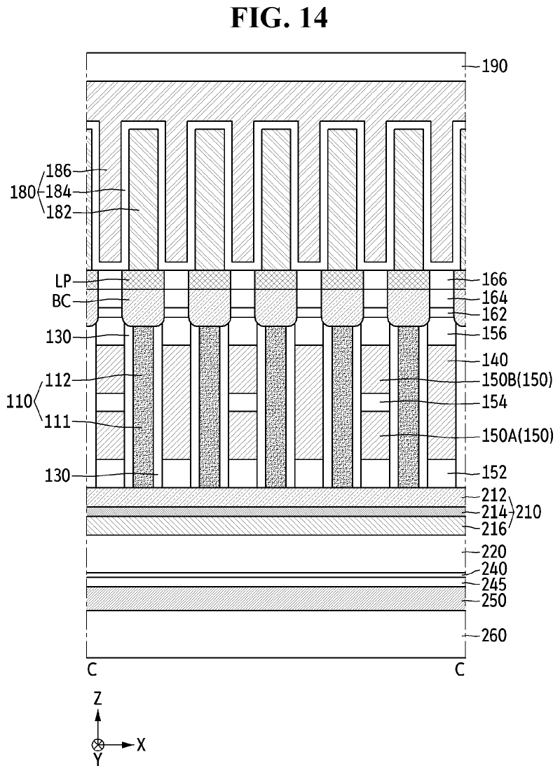

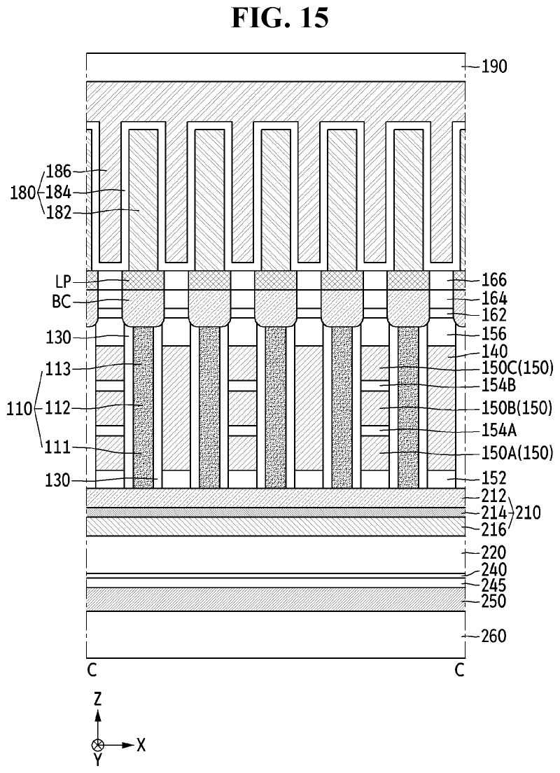

FIG. 13 is an example layout diagram for explaining a semiconductor memory device according to some implementations. FIGS. 14 and 15 are various cross-sectional views taken along C-C of FIG. 13. For convenience of explanation, repeated parts of those explained above using FIGS. 1 to 12b will be briefly described or omitted.

With reference to FIGS. 13 to 15, the semiconductor device according to some implementations further includes a back gate pattern 140.

The back gate pattern 140 may be disposed on a side face of each active pattern 110. The back gate pattern 140 may be spaced apart from each active pattern 110 by a gate dielectric film 130. The back gate pattern 140 may intersect each active pattern 110. For example, the back gate pattern 140 may extend lengthwise in the second horizontal direction Y. The plurality of back gate patterns 140 may be spaced apart from each other in the first horizontal direction X, and extend side by side (or parallel) in the second horizontal direction Y. Each back gate pattern 140 may extend parallel to a row of active patterns 110 arranged along the second horizontal direction Y.

Each active pattern 110 may be interposed between the gate structure 150 and the back gate pattern 140 in the first horizontal direction X. For example, as shown in FIG. 13, the gate structure 150 and the back gate pattern 140 may be alternately arranged along the first horizontal direction X. A row of active patterns 110 arranged along the second horizontal direction Y may be interposed between one gate structure 150 and one back gate pattern 140.

The back gate pattern 140 may be configured to be applied with a voltage to control the corresponding vertical channel transistor. The back gate pattern 140 may be configured to be applied with a voltage independently of the gate structure 150.

As an example, referring to FIG. 14, the high level voltage (e.g., V_{H} of FIG. 4a) equal to or higher than the threshold voltage may be applied to all the first gate pattern 150A, the second gate pattern 150B, and the back gate pattern 140 to turn on the vertical channel transistor corresponding to each active pattern 110.

As another example, referring to FIG. 14, in order to turn off the vertical channel transistor corresponding to each active pattern 110, the lower level voltage (e.g., V_{L} of FIG. 4a) that is equal to or lower than the threshold voltage may be applied to at least one of the first gate pattern 150A or the second gate pattern 150B and the back gate pattern 140.

As an example, referring to FIG. 15, in order to turn on the vertical channel transistor corresponding to each active pattern 110, the lower level voltage (e.g., V_{L} of FIG. 4A) that is equal to or higher than the threshold voltage may be applied to all the first gate pattern 150A, the second gate pattern 150B, the third gate pattern 150C and the back gate pattern 140.

As another example, referring to FIG. 15, in order to turn off the vertical channel transistor corresponding to each active pattern 110, the lower level voltage (e.g., V_{L} of FIG. 10a) that is equal to or higher than the threshold voltage may be applied to at least one of the first gate pattern 150A, the second gate pattern 150B or the third gate pattern 150C and the back gate pattern 140.

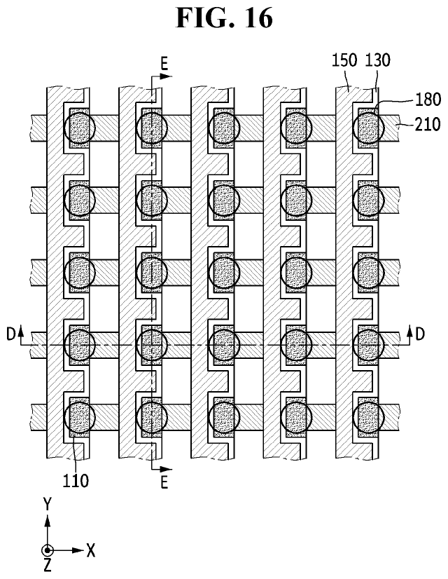

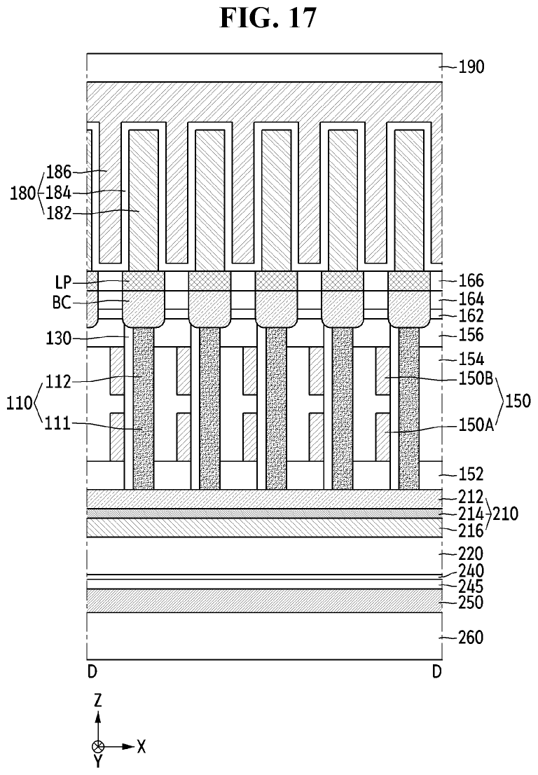

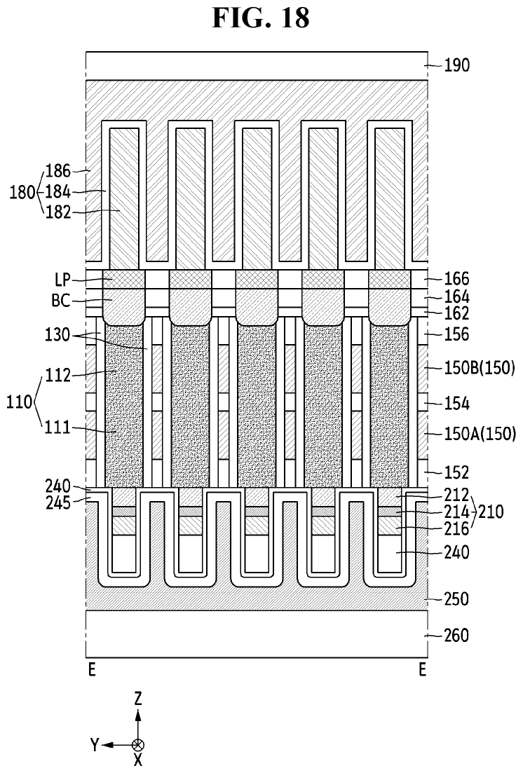

FIG. 16 is a schematic layout diagram for explaining a semiconductor memory device according to some implementations. FIG. 17 is a cross-sectional view taken along line D-D of FIG. 16. FIG. 18 is a cross-sectional view taken along line E-E of FIG. 16. For convenience of explanation, repeated parts of those explained above using FIGS. 1 to 15 will be briefly explained or omitted.

Referring to FIGS. 16 to 18, in the semiconductor device according to some implementations, a part of the gate structure 150 overlaps each active pattern 110 in the second horizontal direction Y.

For example, a part of the first gate pattern 150A may be interposed between a pair of active patterns 110 arranged along the second horizontal direction Y. Alternatively, for example, a part of the second gate pattern 150B may be interposed between a pair of active patterns 110 arranged along the second horizontal direction Y.

In FIG. 16, although the gate structure 150 is only shown to surround only a part (e.g., three sides) of the periphery of each active pattern 110, this is merely example. In some implementations, unlike the shown example, the gate structure 150 may be formed to completely surround (e.g., four sides) the periphery of each active pattern 110.

Hereinafter, a method for fabricating a semiconductor memory device according to the example implementations will be described referring to FIGS. 1 to 28.

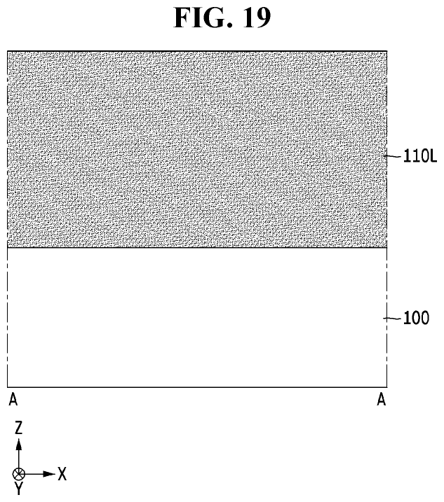

FIGS. 19 to 28 are intermediate stage diagrams for explaining an example method for fabricating the semiconductor memory device according to some implementations. For convenience of explanation, repeated parts of those explained above using FIGS. 1 to 18 will be briefly explained or omitted.

Referring to FIG. 19, an active film 110L is formed on the base substrate 100.

The base substrate 100 may be bulk silicon or silicon on insulator (SOI). The base substrate 100 may be a silicon substrate or may include other materials, for example, silicon germanium, gallium arsenide, silicon germanium on insulator (SGOI), indium antimonide, lead telluride, indium arsenide, indium phosphide or gallium antimonide. Alternatively, the base substrate 100 may be a substrate having an epitaxial layer formed thereon, and may be a ceramic substrate, a quartz substrate, a glass substrate for a display, or the like.

The active film 110L may include a semiconductor material. For example, the active film 110L may include elemental semiconductor materials such as monocrystalline silicon (monocrystalline Si), polycrystalline silicon (polycrystalline Si), amorphous silicon (amorphous Si), silicon germanium (SiGe), silicon germanium on insulator (SGOI), indium antimonide, lead telluride, indium arsenide, indium phosphide, gallium arsenide or gallium antimonide. Alternatively, for example, the active film 110L may include a metal oxide semiconductor material such as indium gallium zinc oxide (IGZO) or indium tin zinc oxide (ITZO). The active film 110L may be formed by etching a part of the base substrate 100, or may be deposited or grown on the base substrate 100.

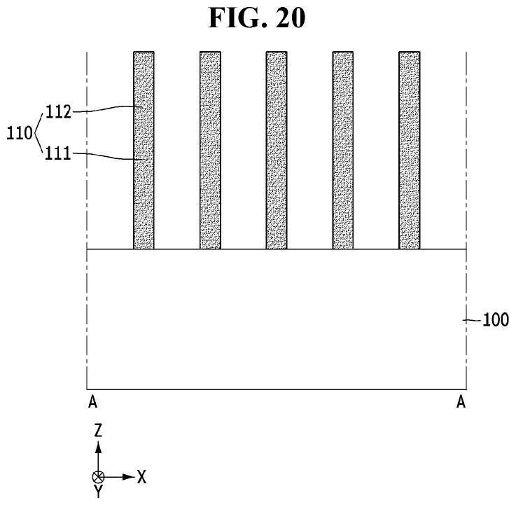

Referring to FIGS. 19 and 20, the active film 110L is patterned to form a plurality of active patterns 110.

The plurality of active patterns 110 may be arranged two-dimensionally along a horizontal plane. For example, the active patterns 110 may be arranged in a matrix shape along the first horizontal direction X and the second horizontal direction Y that intersect each other. Each active pattern 110 may extend lengthwise in the vertical direction Z.

In some implementations, each active pattern 110 may include a first portion 111 and a second portion 112 connected along the vertical direction Z.

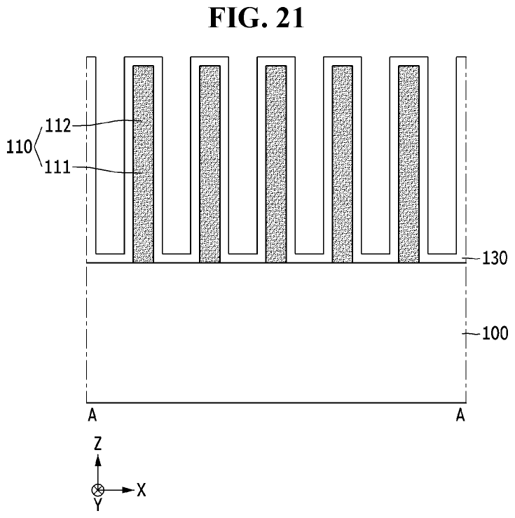

With reference to FIG. 21, a gate dielectric film 130 is formed on the active patterns 110.

For example, the gate dielectric film 130 may extend conformally along the profile of the base substrate 100 and each active pattern 110.

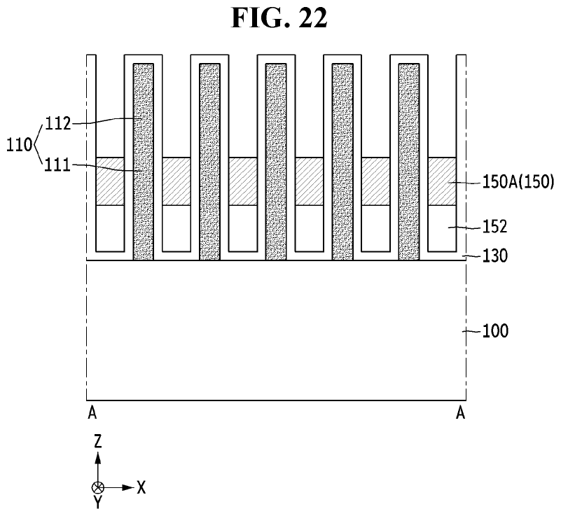

With reference to FIG. 22, a lower spacer 152 and a first gate pattern 150A are formed sequentially on the gate dielectric film 130.

The lower spacer 152 and the first gate pattern 150A may be formed on the side faces of each active pattern 110. For example, an insulating film that covers the gate dielectric film 130 may be formed, and a recess process may be performed on the insulating film. As a result, the lower spacer 152 may be formed from the insulating film. Next, a conductive film that covers the gate dielectric film 130 and the lower spacer 152 may be formed, and a recess process may be performed on the conductive film. As a result, the first gate pattern 150A may be formed from the conductive film.

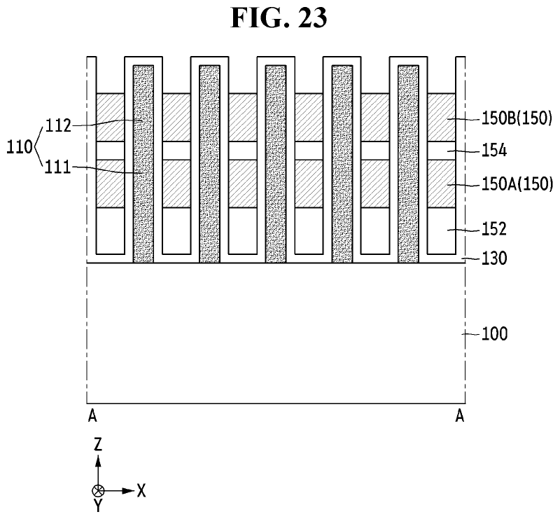

Referring to FIG. 23, an intermediate spacer 154 and a second gate pattern 150B are formed sequentially on the gate dielectric film 130 and the first gate pattern 150A.

The intermediate spacer 154 and the second gate pattern 150B may be formed on the side faces of each active pattern 110. For example, an insulating film that covers the gate dielectric film 130 and the first gate pattern 150A may be formed, and a recess process may be performed on the insulating film. Accordingly, the intermediate spacer 154 may be formed from the insulating film. Next, a conductive film that covers the gate dielectric film 130 and the intermediate spacer 154 may be formed, and a recess process may be performed on the conductive film. Accordingly, the second gate pattern 150B may be formed from the conductive film.

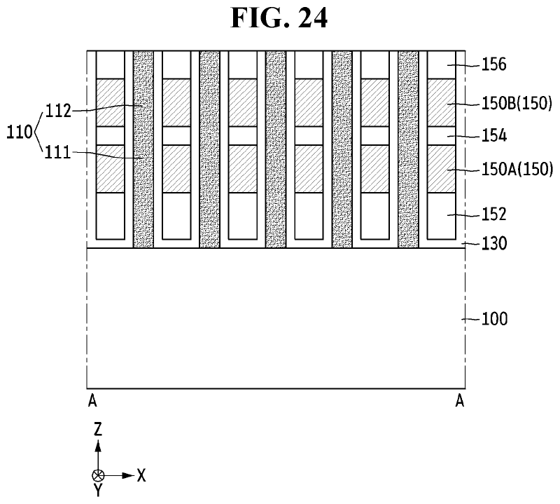

Referring to FIG. 24, an upper spacer 156 is formed on the second gate pattern 150B.

The upper spacer 156 may be formed on the side faces of each active pattern 110. For example, an insulating film that covers the gate dielectric film 130 and the second gate pattern 150B may be formed, and a recess process may be performed on the insulating film. Thus, the upper spacer 156 may be formed from the insulating film.

After the upper spacer 156 is formed, the upper surfaces of each active pattern 110 may be exposed. For example, a planarization process (e.g., a chemical mechanical polishing process) for exposing the upper surfaces of each active pattern 110 may be performed.

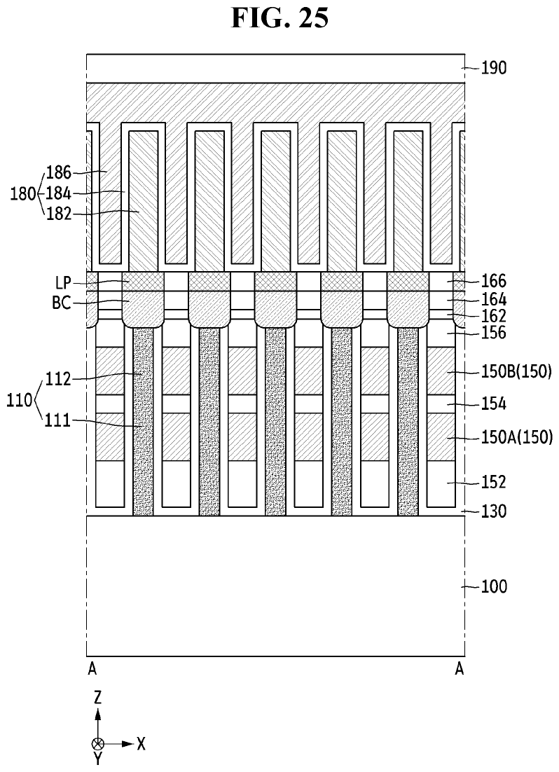

Referring to FIG. 25, a contact pattern BC, a landing pad LP, and a data storage structure 180 are formed.

For example, an etching stop film 162 and a second interlayer insulating film 164 may be sequentially stacked on the plurality of active patterns 110, the gate dielectric film 130, and the upper spacer 156. The contact pattern BC penetrates the etching stop film 162 and the second interlayer insulating film 164, and may be connected to each active pattern 110.

Next, a third interlayer insulating film 166 may be stacked on the second interlayer insulating film 164. The landing pad LP penetrates the third interlayer insulating film 166 and may be connected to the contact pattern BC.

Next, a data storage structure 180 may be formed on the landing pad LP and the third interlayer insulating film 166. The data storage structure 180 may include a lower electrode 182, a capacitor dielectric film 184, and an upper electrode 186, which are stacked sequentially on the landing pad LP. After the data storage structure 180 is formed, an upper insulating film 190 that covers at least a part of the data storage structure 180 may be formed.

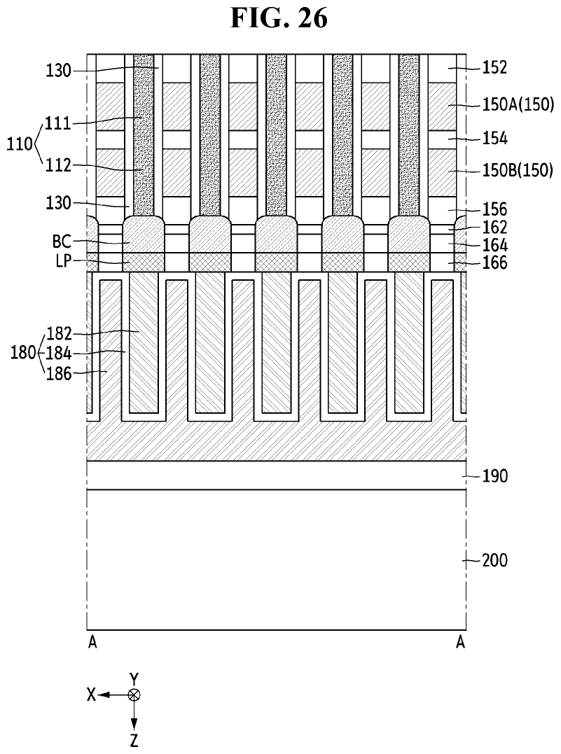

Referring to FIGS. 25 and 26, the base substrate 100 is removed.

For example, a carrier substrate 200 may be attached onto the result of FIG. 25. After the carrier substrate 200 is attached, the result of FIG. 25 may be inverted. Next, a thinning process on the base substrate 100 may be performed. The thinning process may include, but is not limited to, a back grinding process on the back side of the base substrate 100. As the thinning process is performed, the upper surface of each active pattern 110 may be exposed.

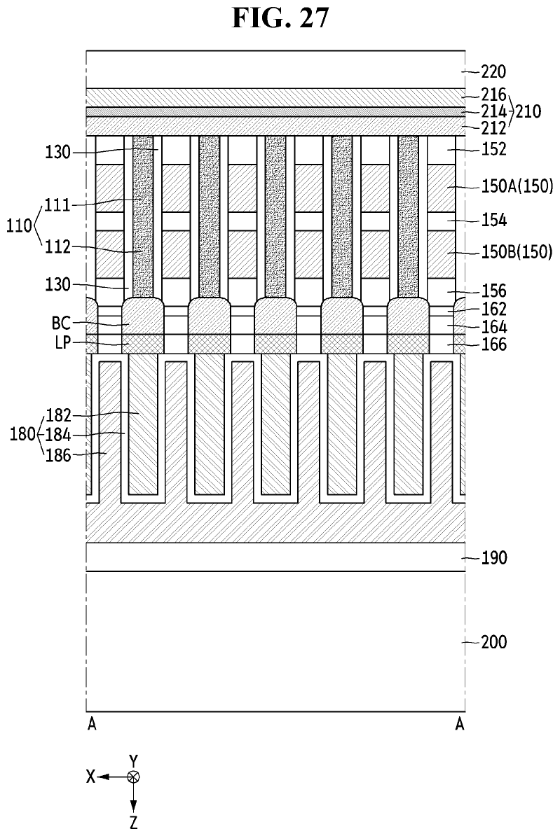

Referring to FIG. 27, a conductive line 210 and a capping film 220 are formed.

For example, the conductive line 210 and the capping film 220 may be sequentially stacked on the plurality of active patterns 110, the gate dielectric film 130, and the lower spacer 152. Each of the conductive line 210 and the capping film 220 may extend lengthwise in the first horizontal direction X. The conductive line 210 may be commonly connected to one row of active patterns 110 arranged along the first horizontal direction X.

In some implementations, the conductive line 210 may include a first conductive film 212, a second conductive film 214, and a third conductive film 216 that are sequentially stacked.

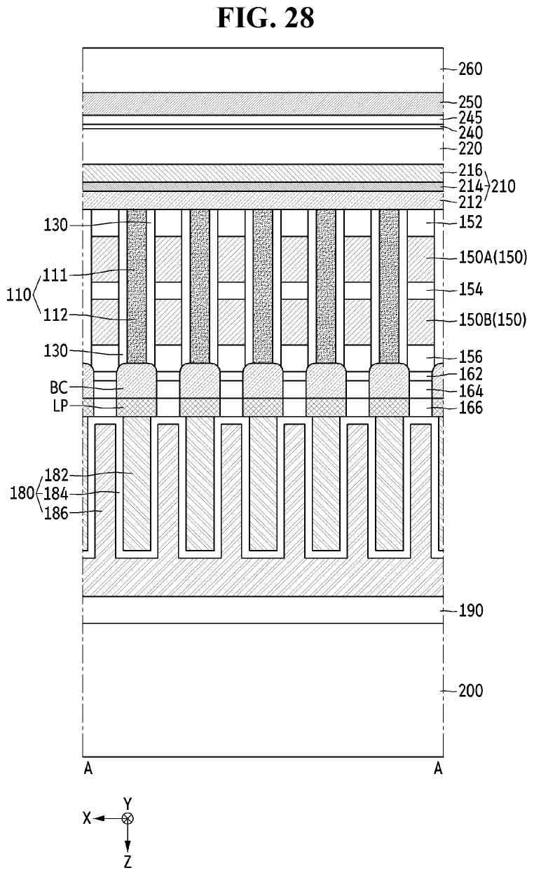

Referring to FIG. 28, a liner film 240, a spacer film 245, and a shield conductive film 250 are formed.

The liner film 240 may be stacked on the conductive line 210 and the capping film 220. The spacer film 245 may be stacked on the liner film 240. The shield conductive film 250 may be stacked on the spacer film 245.

At least a part of the shield conductive film 250 may be interposed between the conductive lines 210 arranged along the second horizontal direction Y. For example, the shield conductive film 250 may be formed to fill at least a part of the region between one conductive line 210 and the other conductive line 210. After the shield conductive film 250 is formed, a lower insulating film 260 that covers at least a part of the shield conductive film 250 may be formed.

Next, referring to FIGS. 1 to 3, the carrier substrate 200 is removed. Accordingly, the semiconductor memory device explained above using FIGS. 1 to 3 may be fabricated.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

Although implementations of the present disclosure have been described with reference to the accompanying drawings, the present disclosure is not limited to the above implementations, but may be implemented in various different forms. A person skilled in the art may appreciate that the present disclosure may be practiced in other concrete forms without changing the technical spirit or essential characteristics of the present disclosure. Therefore, it should be appreciated that the implementations as described above are not restrictive but illustrative in all respects.

What is claimed is:

1. A semiconductor memory device comprising:
an active pattern that includes a first portion and a second portion, wherein the first portion and the second portion are connected along a vertical direction;
a conductive line on a lower surface of the active pattern, wherein the conductive line is connected to the active pattern and extends in a first horizontal direction intersecting the vertical direction;
a first gate pattern on a side face of the first portion of the active pattern, wherein the first gate pattern extends in a second horizontal direction intersecting the vertical direction and the first horizontal direction;
a second gate pattern on a side face of the second portion of the active pattern, wherein the second gate pattern is spaced apart from the first gate pattern and extends in the second horizontal direction; and
a data storage structure on an upper surface of the active pattern, wherein the data storage structure is connected to the active pattern.

2. The semiconductor memory device of claim 1, comprising:
a gate dielectric film that extends along a side face of the active pattern between the active pattern and the first gate pattern, and between the active pattern and the second gate pattern.

3. The semiconductor memory device of claim 1,
wherein the first gate pattern and the second gate pattern overlap in the vertical direction.

4. The semiconductor memory device of claim 1,
wherein the first gate pattern and the second gate pattern are non-overlapping in the vertical direction.

5. The semiconductor memory device of claim 1,
wherein the active pattern includes a third portion connected to the second portion along the vertical direction, and
wherein the semiconductor memory device comprises a third gate pattern on a side face of the third portion of the active pattern, wherein the third gate pattern is spaced apart from the first gate pattern and the second gate pattern and extends in the second horizontal direction.

6. The semiconductor memory device of claim 5,
wherein the first gate pattern, the second gate pattern, and the third gate pattern overlap in the vertical direction.

7. The semiconductor memory device of claim 5,
wherein the first gate pattern and the third gate pattern overlap in the vertical direction, and
wherein the second gate pattern is non-overlapping with the first gate pattern and the third gate pattern in the vertical direction.

8. The semiconductor memory device of claim 1,
wherein a part of the first gate pattern or a part of the second gate pattern overlaps the active pattern in the second horizontal direction.

9. The semiconductor memory device of claim 1,
wherein the data storage structure includes a lower electrode, a capacitor dielectric film, and an upper electrode that are sequentially stacked on the upper surface of the active pattern.

10. The semiconductor memory device of claim 1,
wherein the first gate pattern and the second gate pattern are configured to be applied with voltages independently of each other.

11. A semiconductor memory device comprising:
an active pattern that extends in a vertical direction;
a conductive line on a lower surface of the active pattern, wherein the conductive line is connected to the active pattern and extends in a first horizontal direction intersecting the vertical direction,;
a gate structure on a side face of the active pattern, wherein the gate structure includes a plurality of gate patterns at different levels from each other in the vertical direction and spaced apart from each other, each of the plurality of gate patterns extending in a second horizontal direction intersecting the vertical direction and the first horizontal direction; and
a data storage structure on an upper surface of the active pattern, wherein the data storage structure is connected to the active pattern.

12. The semiconductor memory device of claim 11, comprising:
a lower spacer between the conductive line and the gate structure.

13. The semiconductor memory device of claim 11, comprising:
an upper spacer between the gate structure and the data storage structure.

14. The semiconductor memory device of claim 11,
wherein the data storage structure includes a lower electrode, a capacitor dielectric film, and an upper electrode that are sequentially stacked on the upper surface of the active pattern.

15. The semiconductor memory device of claim 11,
wherein the plurality of gate patterns are configured to be applied with voltages independently of each other.

16. A semiconductor memory device comprising:
an active pattern that includes a first portion and a second portion, wherein the first portion and the second portion are connected along a vertical direction, wherein the active pattern includes a first side face and a second side face opposite to each other in a first horizontal direction intersecting the vertical direction;
a conductive line on a lower surface of the active pattern, wherein the conductive line is connected to the active pattern and extends in the first horizontal direction;
a first gate pattern on the first side face of the first portion, wherein the first gate pattern extends in a second horizontal direction intersecting the vertical direction and the first horizontal direction;
a second gate pattern on the second side face of the second portion, wherein the second gate pattern extends in a second horizontal direction; and
a data storage structure on an upper surface of the active pattern, wherein the data storage structure is connected to the active pattern.

17. The semiconductor memory device of claim 16,
wherein the first gate pattern and the second gate pattern are non-overlapping in the first horizontal direction.

18. The semiconductor memory device of claim 16,
wherein a part of the first gate pattern and a part of the second gate pattern overlap in the first horizontal direction.

19. The semiconductor memory device of claim 16,
wherein the data storage structure includes a lower electrode, a capacitor dielectric film, and an upper electrode that are sequentially stacked on the upper surface of the active pattern.

20. The semiconductor memory device of claim 16,
wherein the first gate pattern and the second gate pattern are configured to be applied with voltages independently of each other.
